(19) United States
(12) Patent Application Publication
(10) Pub. No.: US 2026/0282985 A1
(43) Pub. Date: Sep. 17, 2026

(54) PACKAGE COMPRISING SUBSTRATE WITH IMPROVED SOLDER RESIST LAYER CONFIGURATION

(71) Applicant: QUALCOMM Incorporated, San Diego, CA (US)

(72) Inventors: Joan Rey Villarba BUOT, Escondido, CA (US); Zhijie WANG, San Diego, CA (US); Aniket PATIL, San Diego, CA (US); Seongho KIM, San Diego, CA (US); Hong Bok WE, San Diego, CA (US)

(21) Appl. No.: 19/080,463

(22) Filed: Mar. 14, 2025

(51) Int. Cl. H01L 23/498; H01L 21/48; H01L 23/538; H01L 25/18

(52) U.S. Cl. CPC H10W 70/69; H10W 70/611; H10W 90/00; H10W 90/401; H10W 90/701; H10W 70/05

(57) ABSTRACT

A package comprising a substrate comprising at least one dielectric layer; a plurality of interconnects; and a solder resist layer coupled to a surface of the at least one dielectric layer, wherein the solder resist layer comprises a first portion comprising a first thickness; and a second portion comprising a second thickness. The package further comprises a passive device coupled to the substrate, wherein the passive device vertically overlaps with the first portion of the solder resist layer.

### FIELD

Various features relate to packages with an integrated device and a substrate.

### BACKGROUND

A package may include a substrate and integrated devices. These components are coupled together to provide a package that may perform various electrical functions. There is an ongoing need to provide better performing packages, including packages that are more reliable and/or packages with more robust and reliable connections. Moreover, there is also an ongoing need to reduce and/or minimize the overall size of the packages.

### SUMMARY

Various features relate to packages with an integrated device and a substrate.

One example provides a package that includes a substrate comprising at least one dielectric layer; a plurality of interconnects; and a solder resist layer coupled to a surface of the at least one dielectric layer, wherein the solder resist layer comprises a first portion comprising a first thickness; and a second portion comprising a second thickness. The package further comprises a passive device coupled to the substrate, wherein the passive device vertically overlaps with the first portion of the solder resist layer.

Another example provides a substrate comprising at least one dielectric layer; a plurality of interconnects; and a solder resist layer coupled to a surface of the at least one dielectric layer, wherein the solder resist layer comprises a first portion comprising a first thickness; and a second portion comprising a second thickness.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate with a variable thickness solder resist layer.

FIG. 2 illustrates an exemplary cross sectional profile view of a package that includes a substrate with a variable thickness solder resist layer.

FIG. 3 illustrates an exemplary cross sectional plan view of a package that includes a substrate with a variable thickness solder resist layer.

FIGS. 4A-4C illustrate an exemplary sequence for fabricating a package that includes a substrate with a variable thickness solder resist layer.

FIG. 5 illustrates an exemplary flow chart of a method for fabricating a package that includes a substrate with a variable thickness solder resist layer.

FIGS. 6A-6B illustrate an exemplary sequence for fabricating a substrate with a variable thickness solder resist layer.

FIGS. 7A-7C illustrate an exemplary sequence for fabricating a substrate.

FIG. 8 illustrates an exemplary flow chart of a method for fabricating a substrate.

FIG. 9 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate comprising at least one dielectric layer; a plurality of interconnects; and a solder resist layer coupled to a surface of the at least one dielectric layer, wherein the solder resist layer comprises a first portion comprising a first thickness; and a second portion comprising a second thickness. The package further comprises a passive device coupled to the substrate, wherein the passive device vertically overlaps with the first portion of the solder resist layer. The first portion and the second portion of the solder resist layer may define a tiered cavity in the solder resist layer, which helps keep underfill from overflowing into nearby solder interconnects. This may help provide a reliable high performing package that has a compact form factor.

### Exemplary Package Comprising a Substrate and a Solder Resist Layer

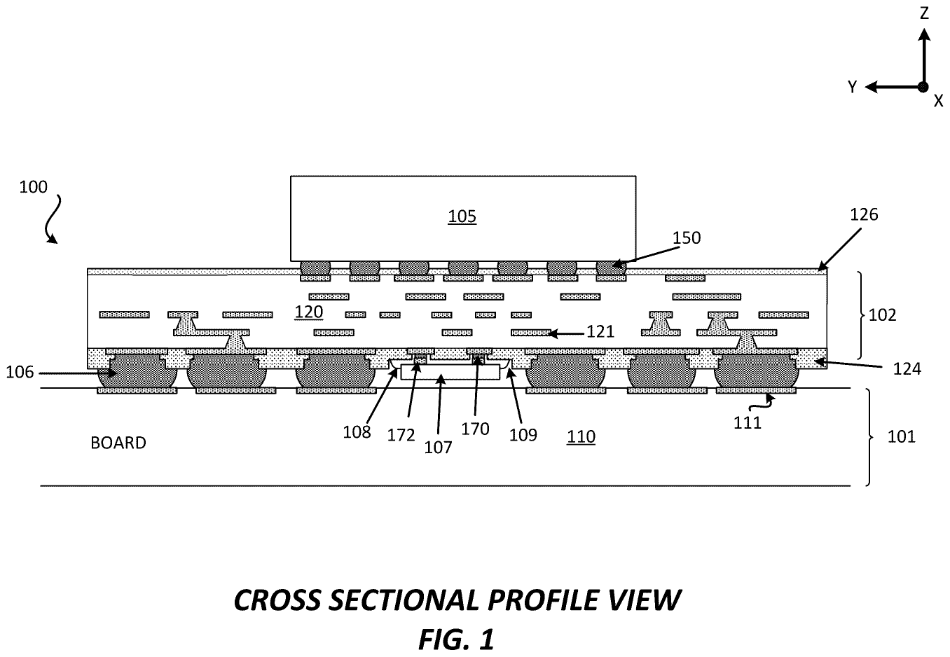

FIG. 1 illustrates an exemplary cross sectional plan view of a package 100 that includes a substrate with an improved solder resist layer configuration. The package 100 may be a package on package (PoP). The package 100 may be coupled to a board 101 through a plurality of solder interconnects 106. The board 101 may include at least one board dielectric layer 110 and a plurality of board interconnects 111. The board 101 may include a printed circuit board (PCB).

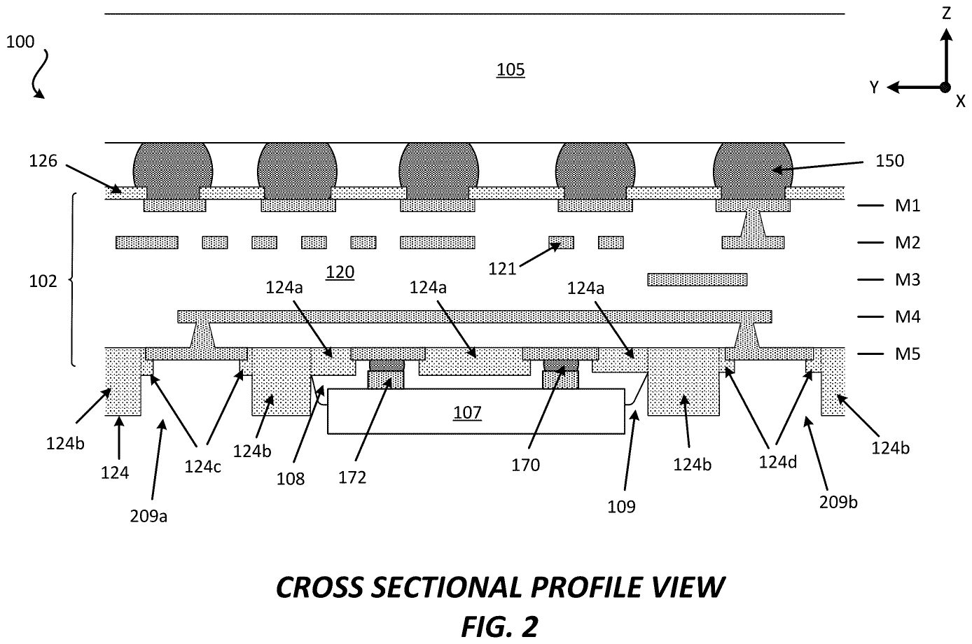

The package 100 may include a substrate 102, an integrated device 105 and a passive device 107. The substrate 102 includes at least one dielectric layer 120, a plurality of interconnects 121, a solder resist layer 124 and a solder resist layer 126. The solder resist layer 126 may include a plurality of cavities and/or openings. The solder resist layer 124 may include a plurality of cavities, including a cavity 109. The cavity 109 in the solder resist layer 124 may be a tiered cavity. The cavity 109 may be an opening and/or a recess in the solder resist layer 124. As will be further described below, the tiered cavity may help prevent underfill from flowing into nearby solder interconnects. A more detailed illustration and description of a tiered cavity in a solder resist layer is further illustrated and described below in at least FIG. 2.

The integrated device 105 may be coupled to the substrate 102 through a plurality of solder interconnects 150. In some implementations, the integrated device 105 may be coupled to the substrate 102 through a plurality of pillar interconnects (not shown) and/or a plurality of solder interconnects 150. The plurality of solder interconnects 150 may be coupled to the integrated device 105 and the landing pad interconnects of the plurality of interconnects 121 of the substrate 102. The substrate 102 may be a coreless substrate. However, different implementations may use different types of substrates.

The passive device 107 is coupled to substrate 102. The passive device 107 may be coupled to a bottom surface of the substrate 102. The passive device 107 may be coupled to landing pad interconnects of the plurality of interconnects 121 of the substrate 102, through a plurality of pillar interconnects 172 and/or a plurality of solder interconnects 170. The passive device 107 may be located at least partially in the cavity 109 of the solder resist layer 124. The passive device 107 may vertically overlap partially with the cavity 109 of the solder resist layer 124. An underfill 108 may be located between the passive device 107 and the substrate 102. The underfill 108 may be located at least partially in the cavity 109 of the solder resist layer 124. The cavity 109 may form a recess and/or an opening in the solder resist layer 124. The underfill 108 may at least partially encapsulate the plurality of pillar interconnects 172 and/or the plurality of solder interconnects 170. The underfill 108 may be laterally surrounded by portions of the solder resist layer 124.

FIG. 2 illustrates a close up view of the package 100. FIG. 2 illustrates that the substrate 102 includes five (5) metal layers. However, different implementations may have different numbers of metal layers. The integrated device 105 is coupled to landing pad interconnects of the plurality of interconnects 121 through a plurality of solder interconnects 150. The substrate 102 includes at least one dielectric layer 120, a plurality of interconnects 121, a solder resist layer 124 and a solder resist layer 126. The solder resist layer 124 includes a cavity 209a, a cavity 209b and a cavity 109. The solder resist layer 124 includes a solder resist layer portion 124a, a solder resist layer portion 124b, a solder resist layer portion 124c, and a solder resist layer portion 124d. In some implementations, the solder resist layer portion 124a may be a first portion of the solder resist layer 124. In some implementations, the solder resist layer portion 124b may be a second portion of the solder resist layer 124. In some implementations, the solder resist layer portion 124c may be a third portion of the solder resist layer 124. In some implementations, the solder resist layer portion 124d may be a fourth portion of the solder resist layer 124. The solder resist layer portion 124a may have a first thickness. The solder resist layer portion 124b may have a second thickness. The second thickness of the solder resist layer portion 124b may be greater than the first thickness of the solder resist layer portion 124a. The solder resist layer portion 124c may have a third thickness. The second thickness of the solder resist layer portion 124b may be greater than the third thickness of the solder resist layer portion 124c. The solder resist layer portion 124d may have a fourth thickness. The second thickness of the solder resist layer portion 124b may be greater than the fourth thickness of the solder resist layer portion 124d. In some implementations, the solder resist layer portion 124a, the solder resist layer portion 124c and/or the solder resist layer portion 124d may have approximately the same thickness.

The cavity 109 in the solder resist layer 124 may be a tiered cavity comprising at least one first cavity that has a first width and/or a first diameter that is defined by the solder resist layer portion 124a and a second cavity that has a second width and/or a second diameter that is defined by the solder resist layer portion 124b. The second width and/or the second diameter may be greater than the first width and/or the first diameter. The cavity 109 may be a tiered cavity that further includes a third cavity that has a third width and/or a third diameter that is defined by the solder resist layer portion 124a. The third width and/or the third diameter may be less than the second width and/or the second diameter. The first cavity and/or the third cavity of the cavity 109 may be openings that allows the passive device 107 to be coupled to interconnects of the substrate 102. In some implementations, the plurality of pillar interconnects 172 and/or the plurality of solder interconnects 170 may be located at least partially in the first cavity and/or the third cavity of the cavity 109 of the substrate 102. The underfill 108 may be located in the first cavity, the second cavity and/or the third cavity of the cavity 109. The cavity 109 may be an opening and/or a recess in the solder resist layer 124. The cavity 109 allows the passive device 107 to be laterally surrounded by a solder resist layer portion (e.g., 124b).

The passive device 107 may be coupled to the substrate 102 through the cavity 109. The passive device 107 may be located at least partially in the cavity 109. The passive device 107 may vertically overlap with the cavity 109. The passive device 107 is coupled to landing pad interconnects of the plurality of interconnects 121 through a plurality of pillar interconnects 172 and a plurality of solder interconnects 170. An underfill 108 may be located between the passive device 107 and the substrate 102. The underfill 108 may be located in the cavity 109 (e.g., in the opening and/or the recess) of the solder resist layer 124. The underfill 108 may be located in the first cavity, the second cavity and/or the third cavity of the cavity 109 (as described above) of the solder resist layer 124. The solder resist layer portion 124b helps prevent the underfill 108 from flowing and touching nearby solder interconnects (e.g., solder interconnects located in the cavity 209a and/or the cavity 209b). The underfill 108 may directly touch the solder resist layer portion 124a and/or the solder resist layer portion 124b.

The cavity 209a in the solder resist layer 124 may be a tiered cavity comprising a first cavity that has a third width and/or a third diameter that is defined by the solder resist layer portion 124c and a second cavity that has a fourth width and/or a fourth diameter that is defined by the solder resist layer portion 124b. The fourth width and/or the fourth diameter may be greater than the third width and/or the third diameter. The cavity 209a may be an opening and/or a recess in the solder resist layer 124. The cavity 209a may expose a landing pad interconnect that is subsequently coupled to a solder interconnect. The solder resist layer portion 124c may vertically overlap with a landing pad interconnect from the plurality of interconnects 121 of the substrate 102.

The cavity 209b in the solder resist layer 124 may be a tiered cavity comprising a third cavity that has a third width and/or a third diameter that is defined by the solder resist layer portion 124d and a second cavity that has a fourth width and/or a fourth diameter that is defined by the solder resist layer portion 124b. The second width and/or the second diameter may be greater than the third width and/or the third diameter. The cavity 209b may be an opening and/or a recess in the solder resist layer 124. The cavity 209a may expose a landing pad interconnect that is subsequently coupled to a solder interconnect. The solder resist layer portion 124d may vertically overlap with a landing pad interconnect from the plurality of interconnects 121 of the substrate 102.

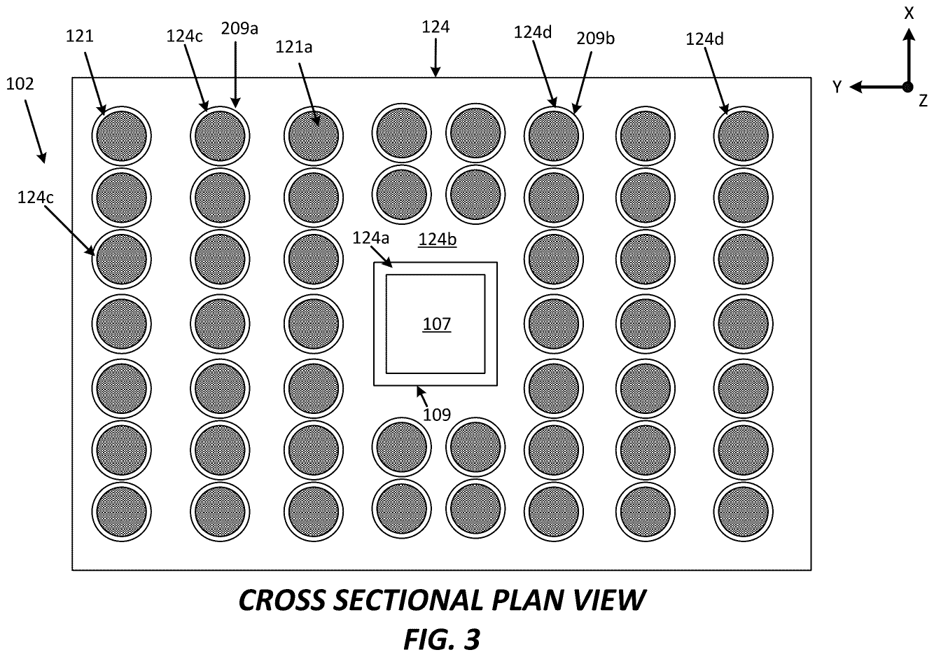

FIG. 3 illustrates an exemplary plan view of the substrate 102 and the passive device 107. The substrate 102 includes a plurality of landing pad interconnects 121a from the plurality of interconnects 121 and a solder resist layer 124. The solder resist layer 124 includes a solder resist layer portion 124a, a solder resist layer portion 124b, a solder resist layer portion 124c and a solder resist layer portion 124d. The solder resist layer 124 includes the cavity 109. The passive device 107 may be located at least in the cavity 109 of the solder resist layer 124. The passive device 107 may vertically overlap with the solder resist layer portion 124a. The passive device 107 may be laterally surrounded (e.g., directly laterally surrounded) by the solder resist layer portion 124b.

The cavity 209a and the cavity 209b may be cavities from a plurality of cavities that have similar configurations and/or arrangements. The cavity 209a and the cavity 209b may be cavities from a plurality of cavities that laterally surround the cavity 109. In some implementations, the cavity 109 may be located approximately about the center of the substrate. However, different implementations may have the cavity 109 at a different location in and/or about the substrate. In implementations, where there are two or more cavities (e.g., 109), each cavity 109 may have a separate passive device (e.g., 109) that is coupled to the substrate 102 through its respective cavity 109. Moreover, each respective cavity 109 may be filled with a respective underfill 108.

An integrated device (e.g., 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc...). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 105) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Package Comprising a Substrate and a Passive Device

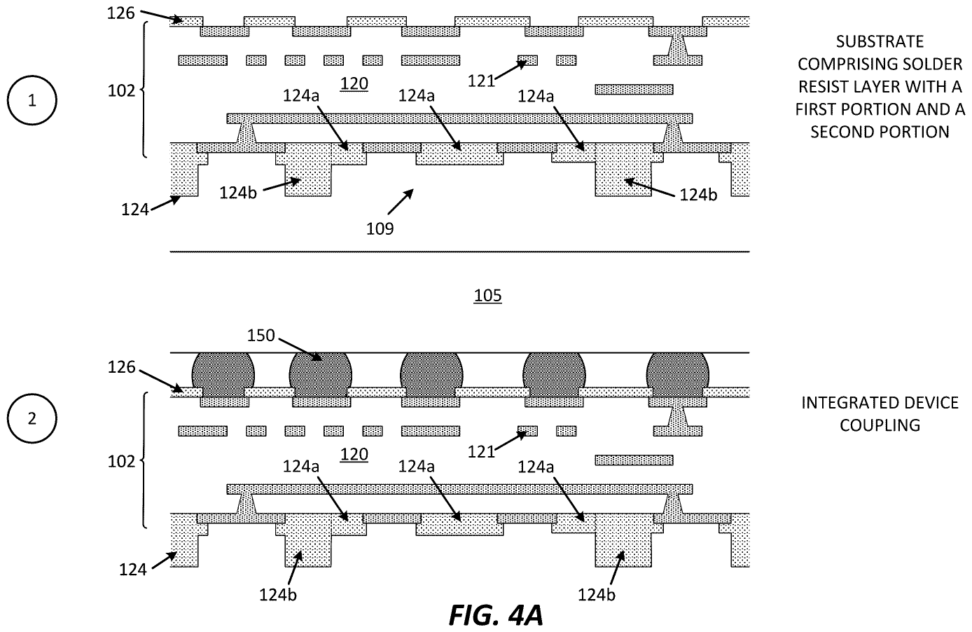

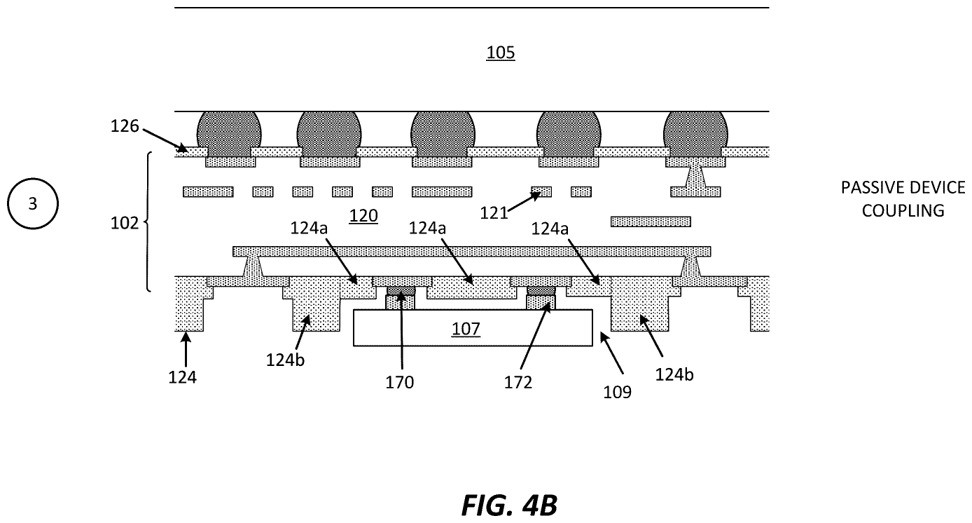

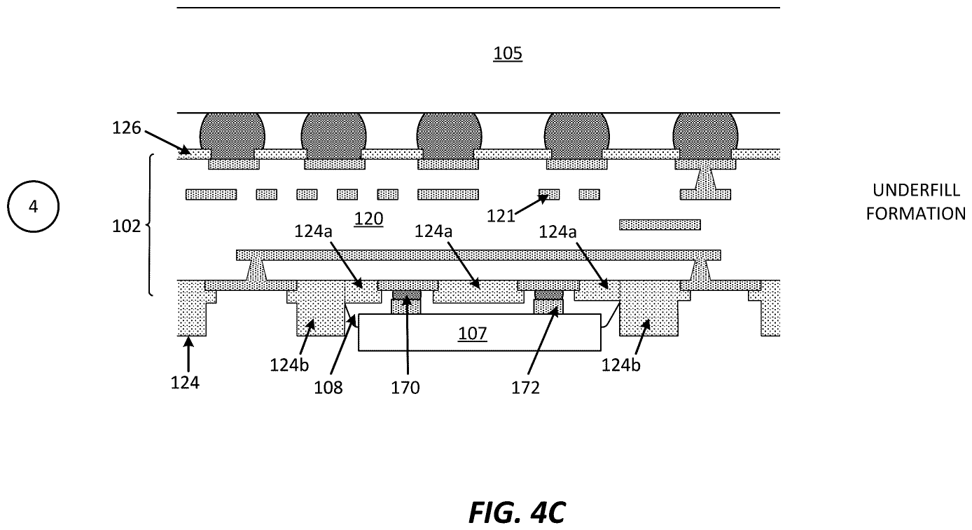

In some implementations, fabricating a package includes several processes. FIGS. 4A-4C illustrate an exemplary sequence for providing or fabricating a package. In some implementations, the sequence of FIGS. 4A-4C may be used to provide or fabricate the package 100. However, the process of FIGS. 4A-4C may be used to fabricate any of the packages described in the disclosure.

It should be noted that the sequence of FIGS. 4A-4C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

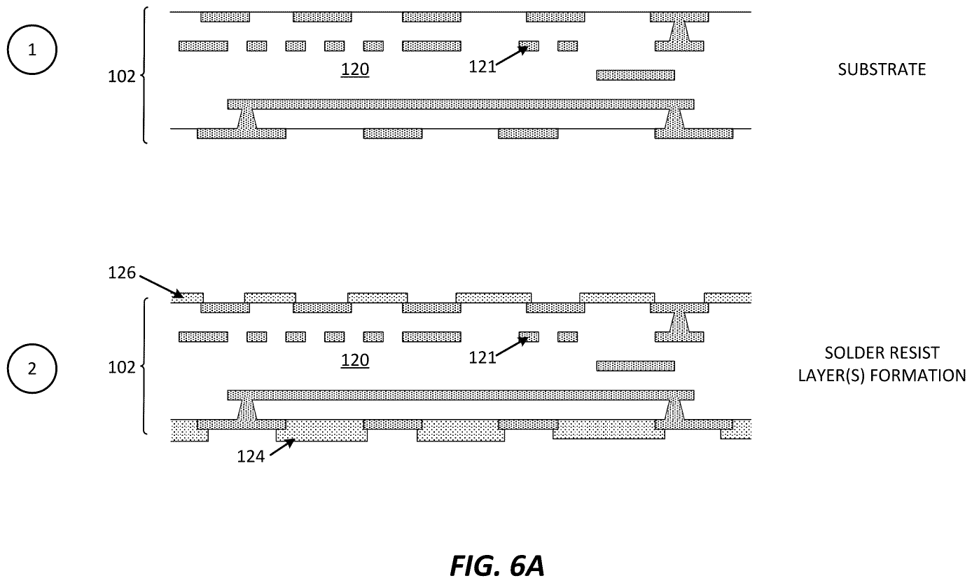

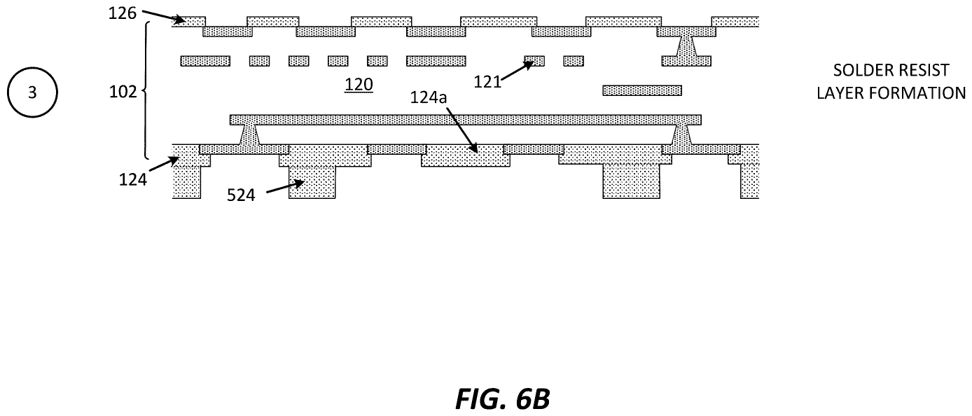

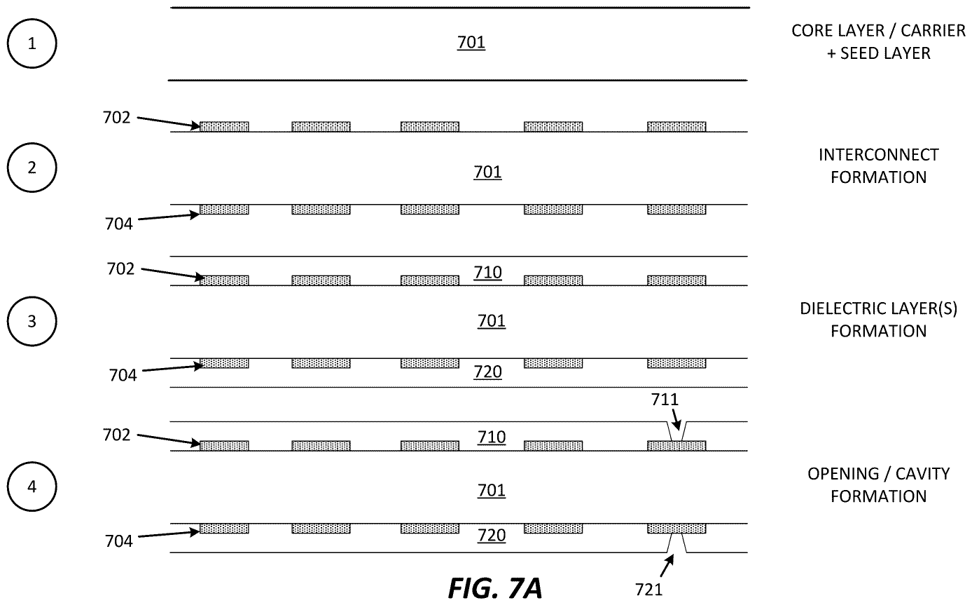

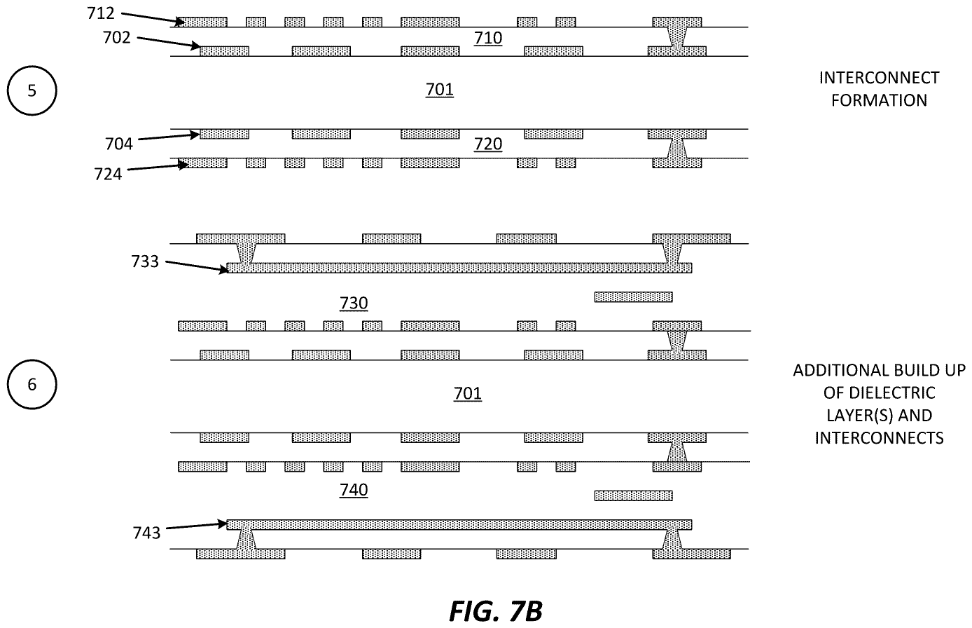

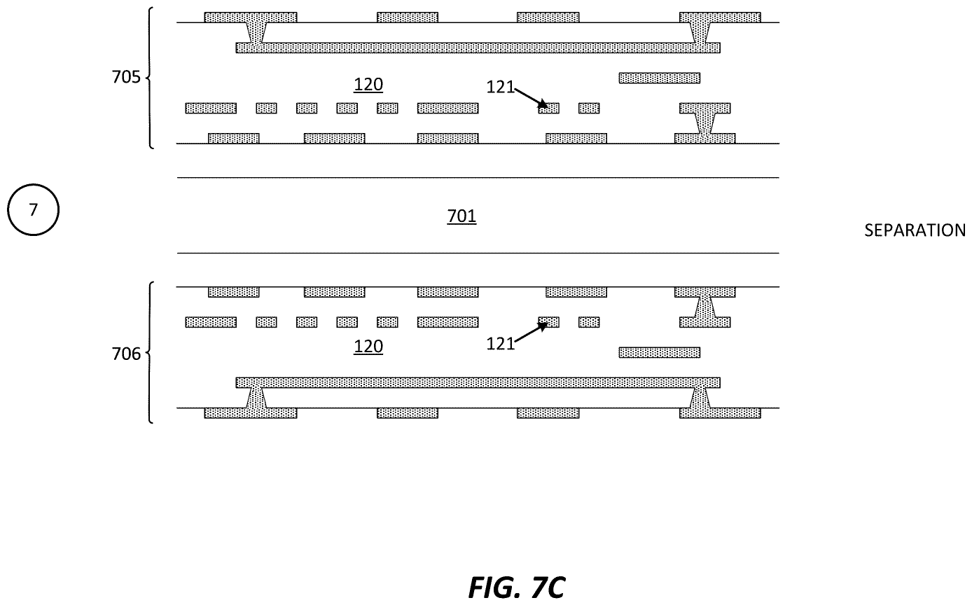

Stage 1, as shown in FIG. 4A, illustrates a state after a substrate 102 is provided. The substrate 102 includes at least one dielectric layer 120, a plurality of interconnects 121, a solder resist layer 124 and a solder resist layer 126. There is a cavity 109 in the solder resist layer 124. The substrate 102 may be fabricated using the method as described in FIGS. 6A-6B and FIGS. 7A-7C.

Stage 2 illustrates a state after an integrated device 105 is coupled to the first surface (e.g., top surface) of the substrate 102. The integrated device 105 is coupled to the substrate 102 through the plurality of solder interconnects 150. A solder reflow process may be used to couple the integrated device 105 to a top surface (e.g., first surface) of the substrate 102.

Stage 3, as shown in FIG. 4B, illustrates a state after the passive device 107 is coupled to the substrate 102 through a plurality of pillar interconnects 172 and a plurality of solder interconnects 170. A solder reflow process may be used to couple the passive device 107 to a bottom surface (e.g., second surface) of the substrate 102. The passive device 107 may be located at least partially in the cavity 109.

Stage 4, as shown in FIG. 4C, illustrates a state after an underfill 108 is provided and/or dispensed in the cavity 109. The underfill 108 may be located between the substrate 102 and the passive device 107. The underfill 108 may be located between the solder resist layer portion 124a and the passive device 107. The underfill 108 may be laterally surrounded by the solder resist layer portion 124b. The underfill 108 may at least partially encapsulate the plurality of pillar interconnects 172 and/or the plurality of solder interconnects 170. The underfill 108 may directly touch the solder resist layer portion 124a and/or the solder resist layer portion 124b.

### Exemplary Flow Diagram of a Method for Fabricating a Package Comprising a Substrate and a Passive Device

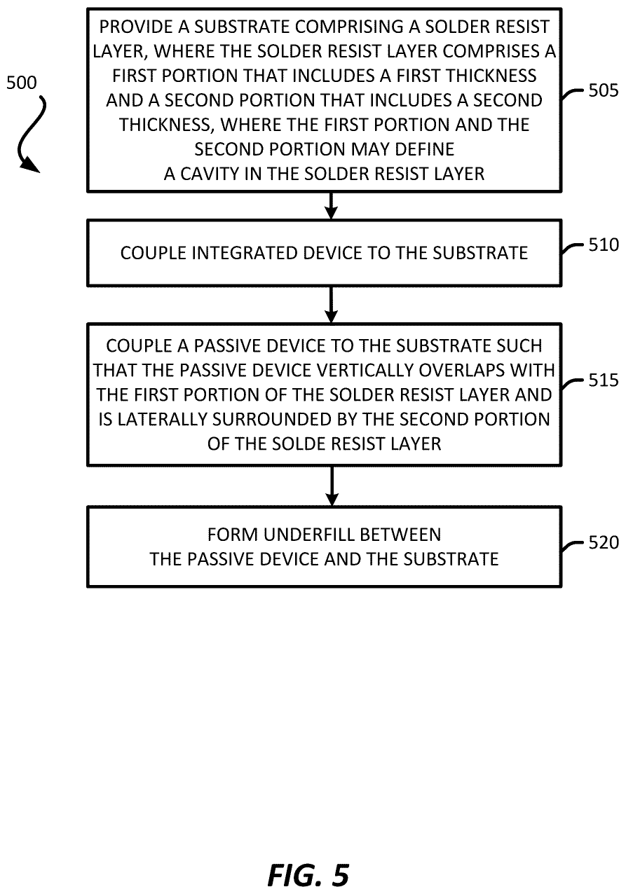

In some implementations, fabricating a package includes several processes. FIG. 5 illustrates an exemplary flow diagram of a method 500 for providing or fabricating a package. In some implementations, the method 500 of FIG. 5 may be used to provide or fabricate the package 100 described in the disclosure. However, the method 500 may be used to provide or fabricate any of the packages described in the disclosure.

It should be noted that the method 500 of FIG. 5 may combine one or more processes in order to simplify and/or clarify the method for providing or fabricating a package. In some implementations, the order of the processes may be changed or modified.

The method provides (at 505) a substrate comprising a solder resist layer with a first portion that includes a first thickness and a second portion that includes a second thickness. The solder resist layer includes a cavity (e.g., tiered cavity). Stage 1 of FIG. 4A, illustrates and describes an example of a state after a substrate 102 is provided. The substrate 102 includes at least one dielectric layer 120, a plurality of interconnects 121, a solder resist layer 124 and a solder resist layer 126. There is a cavity 109 in the solder resist layer 124. The substrate 102 may be fabricated using the method as described in FIGS. 6A-6B and FIGS. 7A-7C.

The method couples (at 510) an integrated device to the substrate. Stage 2 of FIG. 4B, illustrates and describes an example of a state after an integrated device 105 is coupled to the first surface (e.g., top surface) of the substrate 102. The integrated device 105 is coupled to the substrate 102 through the plurality of solder interconnects 150. A solder reflow process may be used to couple the integrated device 105 to the substrate 102.

The method couples (at 515) a passive device to the substrate such that the passive device vertically overlaps with the first portion of the solder resist layer and is laterally surrounded by the second portion of the solder resist layer. Stage 3 of FIG. 4B, illustrates and describes an example of a state after the passive device 107 is coupled to the substrate 102 through a plurality of pillar interconnects 172 and a plurality of solder interconnects 170. A solder reflow process may be used to couple the passive device 107 to the substrate 102. The passive device 107 may be located at least partially in the cavity 109.

The method forms and provides (at 520) an underfill between the passive device and the substrate. Stage 4 of FIG. 4C, illustrates and describes an example of a state after an underfill 108 is provided and/or dispensed in the cavity 109. The underfill 108 may be located between the substrate 102 and the passive device 107. The underfill 108 may be located between the solder resist layer portion 124a and the passive device 107. The underfill 108 may be laterally surrounded by the solder resist layer portion 124b. The underfill 108 may at least partially encapsulate the plurality of pillar interconnects 172 and/or the plurality of solder interconnects 170. The underfill 108 may directly touch the solder resist layer portion 124a and/or the solder resist layer portion 124b.

### Exemplary Sequence for Fabricating a Substrate Comprising Cavities and a Variable Thickness Solder Resist Layer

In some implementations, fabricating a substrate includes several processes. FIGS. 6A-6B illustrate an exemplary sequence for providing or fabricating a substrate. In some implementations, the sequence of FIGS. 6A-6B may be used to provide or fabricate the substrate 102. However, the process of FIGS. 6A-6B may be used to fabricate any of the substrates described in the disclosure.

It should be noted that the sequence of FIGS. 6A-6B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 4A, illustrates a state after a substrate 102 is provided. The substrate 102 includes at least one dielectric layer 120, a plurality of interconnects 121. The substrate 102 may be fabricated using the method as described in FIGS. 7A-7C.

Stage 2 illustrates a state after the solder resist layer 126 and the solder resist layer 124 are provided and/or dispensed on the substrate 102. A lamination process and/or a deposition process may be used to form and provide the solder resist layer 126 and the solder resist layer 124. The solder resist layer 126 may be formed on a first surface of the at least one dielectric layer 120 and the solder resist layer 124 may be formed on a second surface of the at least one dielectric layer 120.

Stage 3, as shown in FIG. 6B, illustrates a state after a solder resist layer 524 is formed, provided and/or dispensed over portions of the solder resist layer 124. A lamination process and/or a deposition process may be used to form and provide the solder resist layer 524. The addition of the solder resist layer 524 to the solder resist layer 124 forms a solder resist layer 124 with different thicknesses and forms at least one opening, at least one cavity and/or at least one recess in the solder resist layer 124 for underfill that will not overflow into other portions of the substrate. The solder resist layer 524 may be considered to be part of the solder resist layer 124. In some implementations, at least one cavity in the solder resist layer may be a tiered cavity.

### Exemplary Sequence for Fabricating a Substrate

In some implementations, fabricating a substrate includes several processes. FIGS. 7A-7C illustrate an exemplary sequence for providing or fabricating a substrate. In some implementations, the sequence of FIGS. 7A-7C may be used to provide or fabricate a laminated substrate. The substrate that is fabricated in FIGS. 7A-7C may replace the substrate 102 of the disclosure.

It should be noted that the sequence of FIGS. 7A-7C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 7A, illustrates a state after a carrier 701 is provided. The carrier 701 may include a core layer. The core layer may include seed layers on surfaces of the core layer.

Stage 2 illustrates a state after a plurality of interconnects 702 and a plurality of interconnects 704 are formed. The plurality of interconnects 702 may be coupled to a first surface (e.g., top surface) of the carrier 701. The plurality of interconnects 704 may be coupled to a second surface (e.g., bottom surface) of the carrier 701. A plating process, a photoresist process, a masking process, an exposure process, a developing process and/or an etching process may be used to form the plurality of interconnects 702 and the plurality of interconnects 704. The plurality of interconnects 702 may be formed on a first seed layer of the carrier 701. The plurality of interconnects 704 may be formed on a second seed layer of the carrier 701.

Stage 3 illustrates a state after a dielectric layer 710 and a dielectric layer 720 are provided. The dielectric layer 710 may be coupled to the first surface of the carrier 701. The dielectric layer 720 may be coupled to the second surface of the carrier 701. A deposition and/or a lamination process may be used to form the dielectric layer 710 and/or the dielectric layer 720. The dielectric layer 710 and/or the dielectric layer 720 may include prepreg, polymer and/or Ajinomoto Build-up Film (ABF).

Stage 4 of FIG. 7B, illustrates a state after a plurality of cavities 711 are formed in the dielectric layer 710, and a plurality of cavities 721 are formed in the dielectric layer 720. An exposure and development process may be used to form the plurality of cavities 711 in the dielectric layer 710 and the plurality of cavities 721 in the dielectric layer 720. Different implementations may use different processes to form the plurality of cavities. The plurality of cavities 711 and/or the plurality of cavities 721 may be openings in dielectric layer(s).

Stage 5 illustrates a state after a plurality of interconnects 712 are formed in the dielectric layer 710, and a plurality of interconnects 724 are formed in the dielectric layer 720. The plurality of interconnects 712 may be coupled to the plurality of interconnects 702. The plurality of interconnects 724 may be coupled to the plurality of interconnects 704. A plating process, a photoresist process, a masking process, an exposure process, a developing process and/or an etching process may be used to form the plurality of interconnects 712 and/or the plurality of interconnects 724.

Stage 6, as shown in FIG. 7C, illustrates a state after additional build up layers are formed. For example, stage 6 illustrates a state after additional dielectric layers and additional interconnects are formed. For example, a dielectric layer 730 may be formed and coupled to the dielectric layer 710. A dielectric layer 740 may be formed and coupled to the dielectric layer 720. A lamination process and/or a deposition process may be used to form the dielectric layer 730 and the dielectric layer 740.

Stage 6 further illustrates a state after a plurality of interconnects 733 are formed in and over the dielectric layer 730, and after a plurality of interconnects 743 are formed in and over the dielectric layer 740. The plurality of interconnects 733 may be coupled to the plurality of interconnects 712. The plurality of interconnects 743 may be coupled to the plurality of interconnects 724. A plurality of cavities may be formed in the dielectric layer 730 and the dielectric layer 740 in a similar manner as described for forming a plurality of cavities in Stage 4 of FIG. 7B. The plurality of interconnects 733 and the plurality of interconnects 743 may be formed in a similar manner as described for fabricating a plurality of interconnects in Stage 5 of FIG. 7B.

Stage 7 illustrates a state after separation of the dielectric layers from the carrier 701. For example, the dielectric layer 710, the dielectric layer 730, the plurality of interconnects 702, the plurality of interconnects 712 and the plurality of interconnects 733 are separated from the carrier 701 to form a substrate 705 (e.g., coreless substrate). In another example, the dielectric layer 720, the dielectric layer 740, the plurality of interconnects 704, the plurality of interconnects 724 and the plurality of interconnects 743 are separated from the carrier 701 to form a substrate 102 (e.g., coreless substrate). The substrate 705 and/or the substrate 706 may be used instead of the substrate 102.

### Exemplary Flow Diagram of a Method for Fabricating a Substrate

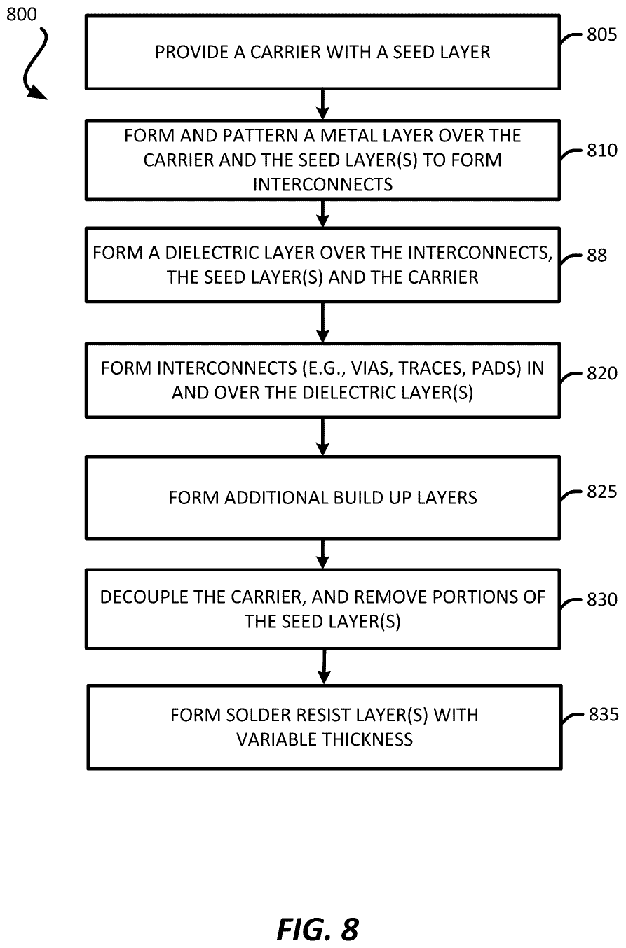

In some implementations, fabricating a substrate includes several processes. FIG. 8 illustrates an exemplary flow diagram of a method 800 for providing or fabricating a substrate. In some implementations, the method 800 of FIG. 8 may be used to provide or fabricate a substrate.

It should be noted that the method 800 of FIG. 8 may combine one or more processes in order to simplify and/or clarify the method for providing or fabricating a substrate. In some implementations, the order of the processes may be changed or modified.

The method provides (at 805) a carrier. The carrier may include seed layers. Stage 1 of FIG. 7A, illustrates and describes an example of a state after a carrier 701 is provided. The carrier 701 may include a core layer. The core layer may include seed layers on surfaces of the core layer.

The method forms (at 810) a plurality of interconnects on the carrier and/or the seed layer(s). Stage 2 of FIG. 7A, illustrates and describes an example of a state after a plurality of interconnects 702 and a plurality of interconnects 704 are formed. The plurality of interconnects 702 may be coupled to a first surface (e.g., top surface) of the carrier 701. The plurality of interconnects 704 may be coupled to a second surface (e.g., bottom surface) of the carrier 701. A plating process, a photoresist process, a masking process, an exposure process, a developing process and/or an etching process may be used to form the plurality of interconnects 702 and the plurality of interconnects 704. The plurality of interconnects 702 may be formed on a first seed layer of the carrier 701. The plurality of interconnects 704 may be formed on a second seed layer of the carrier 701.

The method forms (at 815) at least one dielectric layer over the plurality of interconnects, the seed layer(s) and/or the carrier. Stage 3 of FIG. 7A, illustrates and describes an example of a state after a dielectric layer 710 and a dielectric layer 720 are provided. The dielectric layer 710 may be coupled to the first surface of the carrier 701. The dielectric layer 720 may be coupled to the second surface of the carrier 701. A deposition and/or a lamination process may be used to form the dielectric layer 710 and/or the dielectric layer 720. The dielectric layer 710 and/or the dielectric layer 720 may include prepreg, polymer and/or Ajinomoto Build-up Film (ABF).

The method forms (at 820) interconnects in and over the dielectric layer. For example, via interconnects, trace interconnects and/or pad interconnects may be formed as the interconnects. Forming the plurality of interconnects may include forming a plurality of cavities in the dielectric layer(s). Stage 4 of FIG. 7B, illustrates and describes an example of a state after a plurality of cavities 711 are formed in the dielectric layer 710, and a plurality of cavities 721 are formed in the dielectric layer 720. An exposure and development process may be used to form the plurality of cavities 711 in the dielectric layer 710 and the plurality of cavities 721 in the dielectric layer 720. Different implementations may use different processes to form the plurality of cavities.

Stage 5 of FIG. 7B, illustrates and describes an example of a state after a plurality of interconnects 712 are formed in the dielectric layer 710, and a plurality of interconnects 724 are formed in the dielectric layer 720. The plurality of interconnects 712 may be coupled to the plurality of interconnects 702. The plurality of interconnects 724 may be coupled to the plurality of interconnects 704. A plating process, a photoresist process, a masking process, an exposure process, a developing process and/or an etching process may be used to form the plurality of interconnects 712 and/or the plurality of interconnects 724.

The method forms (at 825) additional build up layers. Stage 6 of FIG. 7C, illustrates and describes an example of a state after additional build up layers are formed. For example, stage 6 illustrates a state after additional dielectric layers and additional interconnects are formed. For example, a dielectric layer 730 may be formed and coupled to the dielectric layer 710. A dielectric layer 740 may be formed and coupled to the dielectric layer 720. A lamination process and/or a deposition process may be used to form the dielectric layer 730 and the dielectric layer 740.

Stage 6 of FIG. 7C, further illustrates and describes an example of a state after a plurality of interconnects 733 are formed in and over the dielectric layer 730, and after a plurality of interconnects 743 are formed in and over the dielectric layer 740. The plurality of interconnects 733 may be coupled to the plurality of interconnects 712. The plurality of interconnects 743 may be coupled to the plurality of interconnects 724. A plurality of cavities may be formed in the dielectric layer 730 and the dielectric layer 740 in a similar manner as described for forming a plurality of cavities in Stage 4 of FIG. 7B. The plurality of interconnects 733 and the plurality of interconnects 743 may be formed in a similar manner as described for fabricating a plurality of interconnects in Stage 5 of FIG. 7B.

The method decouples (at 830) the carrier from the dielectric layers. The method may further remove portions of the seed layer(s). Stage 7 of FIG. 7C, illustrates and describes an example of a state after separation of the dielectric layers from the carrier 701. For example, the dielectric layer 710, the dielectric layer 730, the plurality of interconnects 702, the plurality of interconnects 712 and the plurality of interconnects 733 are separated from the carrier 701 to form a substrate 705 (e.g., coreless substrate). In another example, the dielectric layer 720, the dielectric layer 740, the plurality of interconnects 704, the plurality of interconnects 724 and the plurality of interconnects 743 are separated from the carrier 701 to form a substrate 706 (e.g., coreless substrate). The substrate 705 and/or the substrate 706 may be used instead of the substrate 102, in the package 100 and/or the package 200.

The method may further form (at 835) solder resist layer(s) on the substrate. In some implementations, once separation occurs, one or more solder resist layers may be formed on surface(s) of the substrate 705 and/or the substrate 706. FIGS. 6A-6B illustrate and describe an example of forming a variable thickness solder resist layer.

### Exemplary Electronic Devices

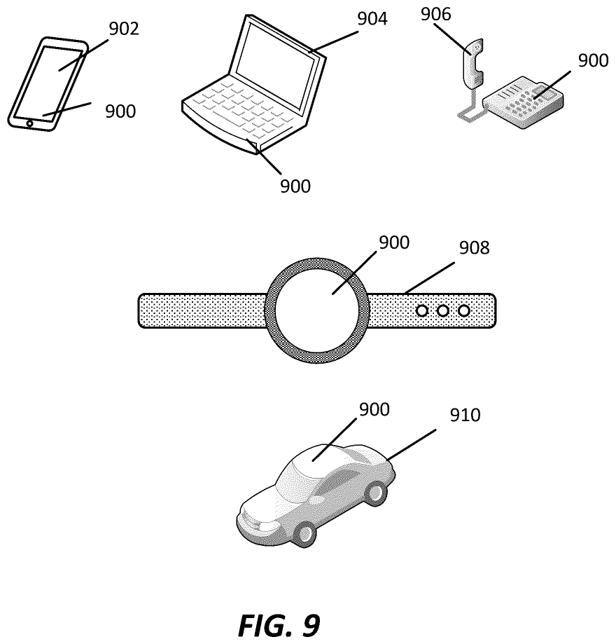

FIG. 9 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 902, a laptop computer device 904, a fixed location terminal device 906, a wearable device 908, or automotive vehicle 910 may include a device 900 as described herein. The device 900 may be, for example, any of the devices and/or integrated circuit (IC) packages described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4B, 5, 6A-6B, 7A-7C and 8-9 may be rearranged and/or combined into a single component, process, feature or function or embodied in several components, processes, or functions. Additional elements, components, processes, and/or functions may also be added without departing from the disclosure. It should also be noted FIGS. 1-3, 4A-4B, 5, 6A-6B, 7A-7C and 8-9 and its corresponding description in the present disclosure is not limited to dies and/or ICs. In some implementations, FIGS. 1-3, 4A-4B, 5, 6A-6B, 7A-7C and 8-9 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate comprising at least one dielectric layer; a plurality of interconnects; and a solder resist layer coupled to a surface of the at least one dielectric layer; wherein the solder resist layer comprises a first portion comprising a first thickness; and a second portion comprising a second thickness; and a passive device coupled to the substrate, wherein the passive device vertically overlaps with the first portion of the solder resist layer.

Aspect 2: The package of aspect 1, wherein the second portion of the solder resist layer laterally surrounds at least part of the passive device.

Aspect 3: The package of aspects 1 through 2, further comprising an underfill located between the passive device and the solder resist layer.

Aspect 4: The package of aspect 3, wherein the underfill vertically overlaps with the first portion of the solder resist layer.

Aspect 5: The package of aspect 4, wherein the underfill is surrounded by the second portion of the solder resist layer.

Aspect 6: The package of aspects 1 through 5, wherein the second thickness is greater than the first thickness.

Aspect 7: The package of aspects 1 through 6, further comprising an integrated device coupled to the substrate.

Aspect 8: The package of aspects 1 through 7, wherein the solder resist layer includes a tiered cavity.

Aspect 9: The package of aspect 8, wherein the tiered cavity comprises a first cavity comprising a first width; and a second cavity comprising a second width that is greater than the first width.

Aspect 10: The package of aspect 9, wherein the first cavity is laterally surrounded by the first portion of the solder resist layer, wherein the second cavity is laterally surrounded by the second portion of the solder resist layer.

Aspect 11: A substrate comprising at least one dielectric layer; a plurality of interconnects; and a solder resist layer coupled to a surface of the at least one dielectric layer; wherein the solder resist layer comprises a first portion comprising a first thickness; and a second portion comprising a second thickness.

Aspect 12: The substrate of aspect 11, further comprising a passive device coupled to the plurality of interconnects of the substrate, wherein the passive device vertically overlaps with the first portion of the solder resist layer, wherein the second portion of the solder resist layer laterally surrounds at least part of the passive device.

Aspect 13: The substrate of aspects 11 through 12, further comprising an underfill located between the passive device and the solder resist layer.

Aspect 14: The substrate of aspect 13, wherein the underfill vertically overlaps with the first portion of the solder resist layer.

Aspect 15: The substrate of aspect 14, wherein the underfill is surrounded by the second portion of the solder resist layer.

Aspect 16: The substrate of aspects 11 through 15, wherein the second thickness is greater than the first thickness.

Aspect 17: The substrate of aspects 11 through 16, further comprising an integrated device coupled to the substrate.

Aspect 18: The substrate of aspects 11 through 17, wherein the solder resist layer includes a tiered cavity.

Aspect 19: The substrate of aspect 18, wherein the tiered cavity comprises a first cavity comprising a first width; and a second cavity comprising a second width that is greater than the first width.

Aspect 20: The substrate of aspect 19, wherein the first cavity is laterally surrounded by the first portion of the solder resist layer, wherein the second cavity is laterally surrounded by the second portion of the solder resist layer.

Aspect 21: The package of aspects 1 through 10, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
at least one dielectric layer;
a plurality of interconnects; and
a solder resist layer coupled to a surface of the at least one dielectric layer, wherein the solder resist layer comprises:
a first portion comprising a first thickness; and
a second portion comprising a second thickness; and
a passive device coupled to the substrate, wherein the passive device vertically overlaps with the first portion of the solder resist layer.

2. The package of claim 1, wherein the second portion of the solder resist layer laterally surrounds at least part of the passive device.

3. The package of claim 1, further comprising an underfill located between the passive device and the solder resist layer.

4. The package of claim 3, wherein the underfill vertically overlaps with the first portion of the solder resist layer.

5. The package of claim 4, wherein the underfill is surrounded by the second portion of the solder resist layer.

6. The package of claim 1, wherein the second thickness is greater than the first thickness.

7. The package of claim 1, further comprising an integrated device coupled to the substrate.

8. The package of claim 1, wherein the solder resist layer includes a tiered cavity.

9. The package of claim 8, wherein the tiered cavity comprises:
a first cavity comprising a first width; and
a second cavity comprising a second width that is greater than the first width.

10. The package of claim 9,
wherein the first cavity is laterally surrounded by the first portion of the solder resist layer,
wherein the second cavity is laterally surrounded by the second portion of the solder resist layer.

11. A substrate comprising:
at least one dielectric layer;
a plurality of interconnects; and
a solder resist layer coupled to a surface of the at least one dielectric layer, wherein the solder resist layer comprises:
a first portion comprising a first thickness; and
a second portion comprising a second thickness.

12. The substrate of claim 11, further comprising a passive device coupled to the plurality of interconnects of the substrate, wherein the passive device vertically overlaps with the first portion of the solder resist layer, wherein the second portion of the solder resist layer laterally surrounds at least part of the passive device.

13. The substrate of claim 11, further comprising an underfill located between the passive device and the solder resist layer.

14. The substrate of claim 13, wherein the underfill vertically overlaps with the first portion of the solder resist layer.

15. The substrate of claim 14, wherein the underfill is surrounded by the second portion of the solder resist layer.

16. The substrate of claim 11, wherein the second thickness is greater than the first thickness.

17. The substrate of claim 11, further comprising an integrated device coupled to the substrate.

18. The substrate of claim 11, wherein the solder resist layer includes a tiered cavity.

19. The substrate of claim 18, wherein the tiered cavity comprises:
a first cavity comprising a first width; and
a second cavity comprising a second width that is greater than the first width.

20. The substrate of claim 19,
wherein the first cavity is laterally surrounded by the first portion of the solder resist layer,
wherein the second cavity is laterally surrounded by the second portion of the solder resist layer.
